(19) United States
(12) Patent Application Publication
(10) Pub. No.: US 2005/0006795 A1
(43) Pub. Date: Jan. 13, 2005

(54) Corner free structure of nonvolatile memory

(76) Inventors: Cheng-Ming Yih, Hsin-Chu City (TW); Huei-Huarng Chen, Chang-Hua (TW); Hong-Chi Chen, Kaohsiung City (TW)

Correspondence Address: LOWE HAUPTMAN GILMAN;& BERNER, LLP, Suite 310, 1700 Diagonal Road, Alexandria, VA, 22314, US

(21) Appl. No.: 10/614,892

(22) Filed: Jul. 9, 2003

(51) Int. Cl. H01L 27/108

(52) U.S. Cl. 257/905

(57) ABSTRACT

A corner free structure of a nonvolatile memory is disclosed in this present invention. The key aspect of this present invention is employing a corner free structure for isolating a trench isolation device and a nonvolatile memory, and thus the reliability of the above-mentioned nonvolatile memory is improved. Furthermore, based on the definition of coupling ratio, as a result of the above-cited corner free structure, the effective channel area of the nonvolatile memory is modified, and thus the nonvolatile memory according to this present invention can achieve higher efficiency than the nonvolatile memory in the prior art. Therefore, this invention can not only improve the reliability of a nonvolatile memory, but also advance the efficiency of the nonvolatile memory.

### BACKGROUND OF THE INVENTION

1. Field of the Invention

This present invention relates to a structure of corner free, and more particularly to a corner free structure of nonvolatile memory.

2. Description of the Prior Art

In recent years, it is well known for employing trench isolation devices, such as shallow trench isolation (STI), to isolate the semiconductor devices. However, corners of the trench isolation devices always come with the trench isolation devices. In the prior art, due to the corners of the trench isolation devices, many unwanted issues of the semiconductor devices will occur.

For instance, FIG. 1 depicts a semiconductor structure according to the prior art. Referred to FIG. 1, the semiconductor structure comprises a substrate 100, and a plurality of trench isolation device 120 in the substrate 100. Corners 125 are usually formed between the substrate 100 and the trench isolation device 120. In point of the nonvolatile memory 130 between two trench isolation devices 120, it is obviously that the tunnel oxide layer 135 of the nonvolatile memory 130 is close to the corners 125, and even the tunnel oxide layer 135 is touched with the corners 125. Therefore, because the trench isolation devices 120 and the nonvolatile memory 130 are not complete isolated, the reliability of the nonvolatile memory 130 is decreased.

Hence, it is an important object of developing a corner free structure for raising the reliability of a nonvolatile memory. Moreover, the above-mentioned corner free structure can increase the efficiency of the nonvolatile memory.

### SUMMARY OF THE INVENTION

In accordance with the present invention, a corner free structure of a nonvolatile memory is provided, wherein the corner free structure efficient isolates the nonvolatile memory and trench isolation devices, and the reliability of the nonvolatile memory is increased.

It is another object of this invention to provide a corner free structure of a nonvolatile memory. According to the definition of coupling ratio, through changing the width of the tunnel oxide layer and the dielectric layer of the nonvolatile memory in this present invention, the efficiency of the above-mentioned nonvolatile memory can be improved.

In accordance with the above-mentioned objects, the invention provides a corner free structure of a nonvolatile memory. The above-mentioned corner free structure of a nonvolatile memory comprises a substrate, at least one trench isolation device, and a plurality of nonvolatile memory. The trench isolation device comprises a corner free structure for complete isolating the nonvolatile memory and the trench isolation device, and thus the reliability of the nonvolatile memory is improved. Additionally, the above-mentioned corner free structure is helpful for modifying the width of the tunnel oxide layer of the nonvolatile memory. Therefore, the corner free structure according to this invention can improve the efficiency of the nonvolatile memory.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a diagram showing a semiconductor structure with trench isolation devices according to the prior art;

FIG. 2 is a corner free structure according to this present invention; and

FIG. 3 is a corner free structure of a nonvolatile memory according to this present invention.

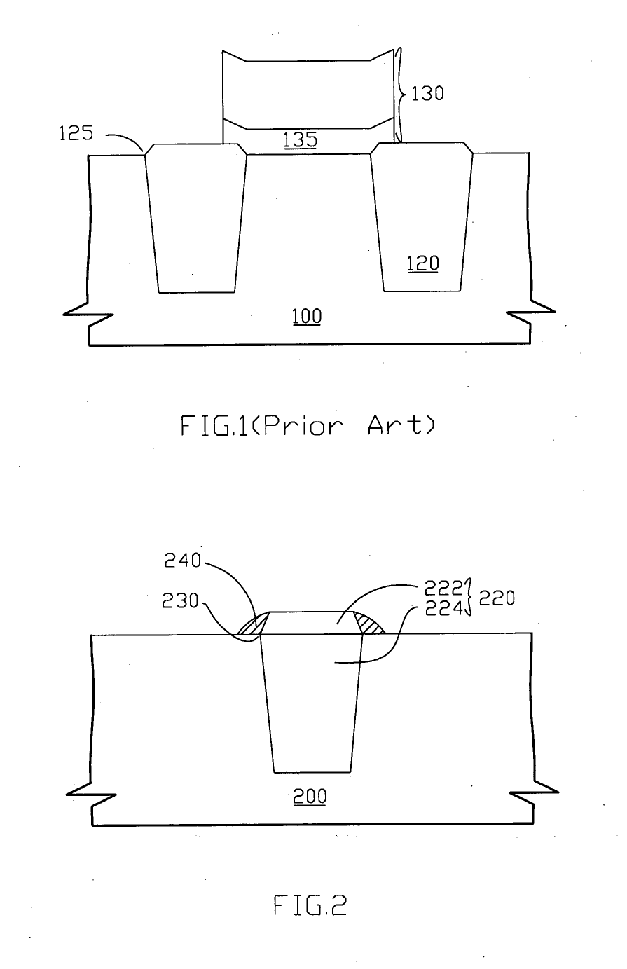

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Then, the components of the semiconductor devices are not shown to scale. Some dimensions are exaggerated to the related components to provide a more clear description and comprehension of the present invention.

One preferred embodiment of this invention is a corner free structure of a nonvolatile memory. The above-mentioned corner free structure of a nonvolatile memory comprises a substrate, and a plurality of trench isolation device. The trench isolation device comprises a first portion on the substrate, and a second portion in the substrate. The above-mentioned trench isolation structure of a nonvolatile memory further comprises a spacer at a sidewall of the first portion of the trench isolation device. The spacer is employed for covering a corner between the sidewall of the first portion of the trench isolation device.

In this preferred embodiment, due to the spacer at the sidewall of the first portion of the trench isolation device, the tunnel oxide layer of a nonvolatile memory between two trench isolation device is kept from the corner of the trench isolation device, and thus the reliability of the nonvolatile memory is improved. On the other hand, the width of the nonvolatile memory is modified by the spacer of the trench isolation device. In other words, the width of the tunnel oxide layer of the nonvolatile memory is decreased, and the width of the dielectric layer of the nonvolatile memory is increased. According to the definition of coupling ratio, the above-mentioned width modification of the nonvolatile memory can improve the coupling ratio of the nonvolatile memory. Hence, the efficiency of the nonvolatile memory according to this present embodiment is better than the efficiency of the nonvolatile memory in the prior art.

Another preferred embodiment of this present invention is about a corner free structure of a nonvolatile memory. Referred to FIG. 2, the corner free structure according with this present embodiment comprises a substrate 200, and at least one trench isolation device 220. The trench isolation device 220 may be shallow trench isolation (STI). The trench isolation device 220 comprises a first portion 222 on the substrate 200, and a second portion 224 in the substrate 200.

Corners 230 are formed between the first portion 222 of the trench isolation device 220 and the substrate 200. In the prior art, because the corner 230 is close to the tunnel oxide layer of the nonvolatile memory or touched with the tunnel oxide layer of the nonvolatile memory, the reliability of the nonvolatile memory will be decreased. Therefore, in this present embodiment, a spacer 240 is at a sidewall of the first portion 222 of the trench isolation device 220, and covers the corner 230 between the sidewall of the first portion 222 of the trench isolation 220 and the substrate 200. The spacer 240 is consisted of deposited silicon dioxide, deposited silicon nitride, and the like dielectric materials. The spacer 240 can be formed by the technology in the prior art. For example, the spacer 240 may be formed at the sidewall of the first portion 222 by a depositing step and an etching step. In this manner, the trench isolation device 220 and the tunnel oxide layer of the nonvolatile memory can be efficiently isolate the spacer 240, and thus the reliability of the nonvolatile memory can be improved.

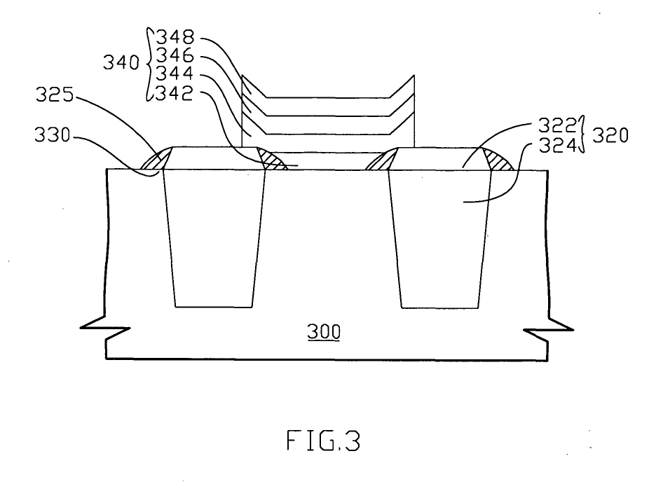

Another preferred embodiment according to this invention is a corner free structure of a nonvolatile memory. As shown in FIG. 3, the corner free structure of a nonvolatile memory comprises a substrate 300, a plurality of trench isolation device 320, and a plurality of nonvolatile memory 340, wherein each of the nonvolatile memory is between two trench isolation devices 320. The substrate comprises silicon. The trench isolation device may be shallow trench isolation. The above-mentioned trench isolation device comprises a first portion 322 on the substrate 300, and a second portion 324 in the substrate 300. As the trench isolation device 220 in the above-mentioned embodiment, corner 330 is formed between the first portion 322 of the trench isolation device 320 and the substrate 300. In order to preventing the issues in the prior art, the trench isolation device 320 also comprises a spacer 325 at the sidewall of the first portion 322 of the trench isolation device 320 for covering the corner 330 between the first portion 322 and the substrate 300. The material of the spacer 325 may be deposited silicon dioxide, deposited silicon nitride, or other dielectric materials. The spacer 325 may be formed by ordinary technology. For instance, after depositing a dielectric material layer onto the substrate 300 and the trench isolation device 320, and etching parts of the above-mentioned dielectric material layer, the spacer 325 is formed at the sidewall of the first portion 322 of the trench isolation device 320. Therefore, the spacer 325 can efficiently keep the tunnel oxide layer of the nonvolatile memory 340 from touching the corner 330. In other words, the reliability of the nonvolatile memory according to this embodiment can be improved by the spacer 325.

Referred to FIG. 3, a nonvolatile memory 340 is disposed between two trench isolation devices 320. The nonvolatile memory 340 may be flash memory. The nonvolatile memory 340 comprises a tunnel oxide layer 342 on the substrate, a floating gate 344 on the tunnel oxide layer 342, a dielectric layer 346 on the floating gate 344, and a control gate 348 on the dielectric layer 346. In this present embodiment, the coupling ratio may be defined as the ratio between the capacitive value of the dielectric layer 346 and the sum of the capactive value of the dielectric layer 344 and width of the tunnel oxide layer 342, as shown in the equation 1.
coupling ratio=B/B+A (equation 1)

In the equation 1, A is the capacitive value of the tunnel oxide layer 342, and B is the capacitive value of the dielectric layer 346. In the point of a nonvolatile memory, coupling ratio is relative to the efficiency of the nonvolatile memory. From FIG. 3, due to the existence of spacer 325 in this embodiment, the capacitive value A of the tunnel oxide layer 342 is decreased because the width of the tunnel oxide layer 342 is decreased. Consequently, according to the definition of coupling ratio of a nonvolatile memory, the nonvolatile memory according to this embodiment can achieve higher efficiency.

According to the preferred embodiments, this invention discloses a corner free structure of a nonvolatile memory. The corner free structure of a nonvolatile memory comprises a substrate, at least a trench isolation device, and a plurality of nonvolatile memory, wherein each of the nonvolatile memory is disposed between two trench isolation devices. The above-mentioned trench isolation device comprises a first portion on the substrate, and a second portion in the substrate. The corner free structure of a nonvolatile memory further comprises a spacer at a sidewall of the first portion of the trench isolation device. The spacer is utilized for covering a corner between the substrate and the sidewall of the first portion of the trench isolation device. The trench isolation device and the tunnel oxide layer of the nonvolatile memory can be efficiently isolated by the spacer. Hence, the reliability of a nonvolatile memory can be advanced by the corner free structure according to this invention. On the other hand, as a result of the spacer according to this invention, the width of the tunnel oxide layer of the nonvolatile memory is decreased, and the width of the dielectric layer of the nonvolatile memory is increased. Therefore, based on the definition of coupling ratio, the nonvolatile memory according to this present invention can achieve higher efficiency than the nonvolatile memory in the prior art.

Although specific embodiments have been illustrated and described, it will be obvious to those skilled in the art that various modifications may be made without departing from what is intended, but not to be limited solely by the appended claims.

1. A corner free structure of a nonvolatile memory, comprising:
a substrate;
at least a trench isolation device comprising a first portion on said substrate and a second portion in said substrate; and
a spacer at a sidewall of said first portion, wherein said spacer covers a corner between said sidewall and said substrate.

2. The structure according to claim 1, further comprises at least a nonvolatile memory using said trench isolation device.

3. The structure according to claim 1, wherein said spacer is deposited silicon dioxide.

4. The structure according to claim 1, wherein said spacer is deposited silicon nitride or other isolated materials.

5. The structure according to claim 1, wherein a formation of said spacer comprises following steps:
depositing a dielectric material layer onto said substrate and said trench isolation device; and
etching said dielectric material layer to form said spacer at said sidewall of said first portion.

6. The structure according to claim 1, wherein said trench isolation device is shallow trench isolation.

7. A corner free structure of nonvolatile memory, comprising:
a substrate;
a plurality of trench isolation device, each of said trench isolation devices comprises a first portion on said substrate and a second portion in said substrate;
a spacer at a sidewall of said first portion, wherein said spacer covers a corner between said sidewall and said substrate; and
at least a nonvolatile memory using said trench isolation device.

8. The structure according to claim 7, wherein said trench isolation device is shallow trench isolation.

9. The structure according to claim 7, wherein said nonvolatile memory is flash memory.

10. The structure according to claim 7, wherein a formation of said spacer comprises following steps:
depositing a dielectric material layer onto said substrate and said trench isolation device; and
etching said dielectric material layer to form said spacer at said sidewall of said first portion.

11. The structure according to claim 7, wherein said spacer is deposited silicon dioxide.

12. The structure according to claim 7, wherein said spacer is deposited silicon nitride.

13. The structure according to claim 7, wherein said nonvolatile memory comprises a tunnel oxide layer.

14. A corner free structure of nonvolatile memory, comprising:
a substrate;
a plurality of shallow trench isolation, each of said shallow trench isolations comprises a first portion on said substrate and a second portion in said substrate;
a spacer at a sidewall of said first portion of said shallow trench isolation, wherein said spacer covers a corner between said sidewall and said substrate; and
at least a flash memory between two of said shallow trench isolations.

15. The structure according to claim 14, wherein a formation of said spacer comprises following steps:
depositing a dielectric material layer onto said substrate and said trench isolation device; and
etching said dielectric material layer to form said spacer at said sidewall of said first portion.

16. The structure according to claim 14, wherein said spacer is deposited silicon dioxide.

17. The structure according to claim 14, wherein said spacer is deposited silicon nitride.
